(19) United States
(12) Patent Application Publication
(10) Pub. No.: US 2026/0040528 A1
(43) Pub. Date: Feb. 5, 2026

(54) SEMICONDUCTOR MEMORY DEVICE

(71) Applicant: SAMSUNG ELECTRONICS CO., LTD., Suwon-si (KR)

(72) Inventors: Hyungki Cho, Suwon-si (KR); Gunjoo Woo, Suwon-si (KR); Kyeongju Moon, Suwon-si (KR); Kihyung Sim, Suwon-si (KR); Minji HONG, Suwon-si (KR)

(73) Assignee: SAMSUNG ELECTRONICS CO., LTD., Suwon-si (KR)

(21) Appl. No.: 19/201,468

(22) Filed: May 7, 2025

(30) Foreign Application Priority Data
Aug. 1, 2024 (KR) 10-2024-0102363

(51) Int. Cl. H10B 12/00

(52) U.S. Cl. CPC H10B 12/33; H10B 12/05

(57) ABSTRACT

Provided is a semiconductor memory device. This device includes a substrate, an active pattern perpendicular to an upper surface of the substrate, the active pattern having a first end portion and a second end portion opposite to each other and a first side surface and a second side surface opposite to each other and connecting the first end portion to the second end portion, a word line adjacent to the first side surface of the active pattern, a storage node contact plug contacting the first end portion of the active pattern, a conductive pattern contacting both the first end portion and the storage node contact plug, and a bit line contacting the second end portion of the active pattern, wherein the storage node contact plug includes first metal, and the conductive pattern includes second metal having higher oxidizing power than the first metal.

### CROSS-REFERENCE TO RELATED APPLICATION

This U.S. non-provisional patent application claims priority to Korean Patent Application No. 10-2024-0102363, filed on Aug. 1, 2024, the entire contents of which are hereby incorporated by reference.

### BACKGROUND

### 1. Field

The present disclosure relates to a semiconductor memory device, and more particularly, to a semiconductor memory device including vertical channel transistors.

### 2. Description of Related Art

Manufacturing technology for semiconductor memory devices is being developed to improve the integration, operational speed, and yield of semiconductor devices. Accordingly, transistors having vertical channels for increasing the integration, resistance, current driving ability, and the like of the transistors have been proposed.

### SUMMARY

Provided is a semiconductor memory device with improved electrical characteristics and integration density.

According to an aspect of the disclosure, a semiconductor memory device includes: a substrate; an active pattern perpendicular to an upper surface of the substrate, the active pattern comprising a first end portion, a second end portion, a first side surface, and a second side surface, the first end portion being opposite to the second end portion, the first side surface being opposite to the second side surface, and the first side surface and the second side surface connecting the first end portion to the second end portion; a word line adjacent to the first side surface of the active pattern and extending in a first direction parallel with the upper surface of the substrate; a storage node contact plug in contact with the first end portion of the active pattern; a conductive pattern in contact with both the first end portion and the storage node contact plug; and a bit line in contact with the second end portion of the active pattern, wherein the storage node contact plug comprises a first metal having a first oxidizing power, and wherein the conductive pattern comprises a second metal having a second oxidizing power that is higher than the first oxidizing power of the first metal.

According to an aspect of the disclosure, a semiconductor memory device includes: a substrate; a first active pattern and a second active pattern, the first and the second active patterns being perpendicular to an upper surface of the substrate and the first active pattern being spaced apart from the second active pattern in a first direction; a mold pattern between the first and the second active patterns; a first word line between the mold pattern and the first active pattern; a second word line between the mold pattern and the second active pattern; a gate insulating layer between the first active pattern and the first word line and between the second active pattern and the second word line, wherein the gate insulating layer is on an upper surface of the mold pattern; storage node contact plugs that are respectively in contact with lower portions of the first and the second active patterns and which at least partially overlap the first and the second word lines; a bit line connecting upper portions of the first and the second active patterns; a separation insulating pattern between the storage node contact plugs and at least partially overlapping the mold pattern, wherein a portion of the separation insulating pattern is between the first and the second word lines and the storage node contact plugs; and conductive patterns between the separation insulating pattern and the storage node contact plugs, wherein the conductive patterns are in contact with the first and the second active patterns, wherein the storage node contact plugs comprise a first metal, and wherein the conductive patterns comprise a second metal different from the first metal.

According to an aspect of the disclosure, a semiconductor memory device includes: a substrate; an active pattern perpendicular to an upper surface of the substrate, the active pattern comprising a first side surface and a second side surface, the first side surface being opposite to the second side surface; a storage node contact plug in contact with a lower surface of the active pattern; a conductive pattern in contact with a lower portion of the first side surface of the active pattern and an upper surface of the storage node contact plug; a bit line in contact with an upper surface of the active pattern; a word line on the conductive pattern and adjacent to the first side surface of the active pattern; and a first insulating layer, a second insulating layer, and a third insulating layer sequentially arranged on the second side surface of the active pattern, wherein the third insulating layer comprises hydrogen, and wherein the second insulating layer prevents penetration of the hydrogen of the third insulating layer.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a block diagram illustrating a semiconductor memory device according to one or more embodiments of the disclosure;

FIG. 2 is a perspective view schematically illustrating a semiconductor memory device according to one or more embodiments of the disclosure;

FIG. 3A is a plan view of a semiconductor memory device according to one or more embodiments of the disclosure;

FIG. 3B shows cross-sectional views taken along line A-A′ and line B-B′ of FIG. 3A according to one or more embodiments of the disclosure;

FIGS. 4A, 4B, 4C, 4D and 4E are enlarged views of portion P1 of FIG. 3B according to one or more embodiments of the disclosure;

FIGS. 5A and 5B show cross-sectional views taken along line A-A′ and line B-B′ of FIG. 3A according to one or more embodiments of the disclosure;

FIGS. 6A, 7A, 8A, 9A, 10A, 11A, 12A, and 13A are plan views sequentially illustrating a process of manufacturing the semiconductor memory device of FIG. 3A; and

FIGS. 6B, 7B, 8B, 9B, 10B, 11B, 12B, 13B, 14, and 15 are cross-sectional views sequentially illustrating a process of manufacturing the semiconductor memory device of FIG. 3B.

### DETAILED DESCRIPTION

Hereinafter, one or more embodiments according to the disclosure will be described in detail with reference to the drawings in order to describe the disclosure in more detail. Herein, the terms indicating order, such as first, second, etc., are used to distinguish elements having the same/similar functions, and the ordinal numbers may be interchanged according to the order in which the terms are mentioned. Terms indicating positional relationships (e.g., top surface, upper portion, upper surface, bottom surface, lower surface, lower portion, on or under) may be interchanged according to the direction of viewing the drawings.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

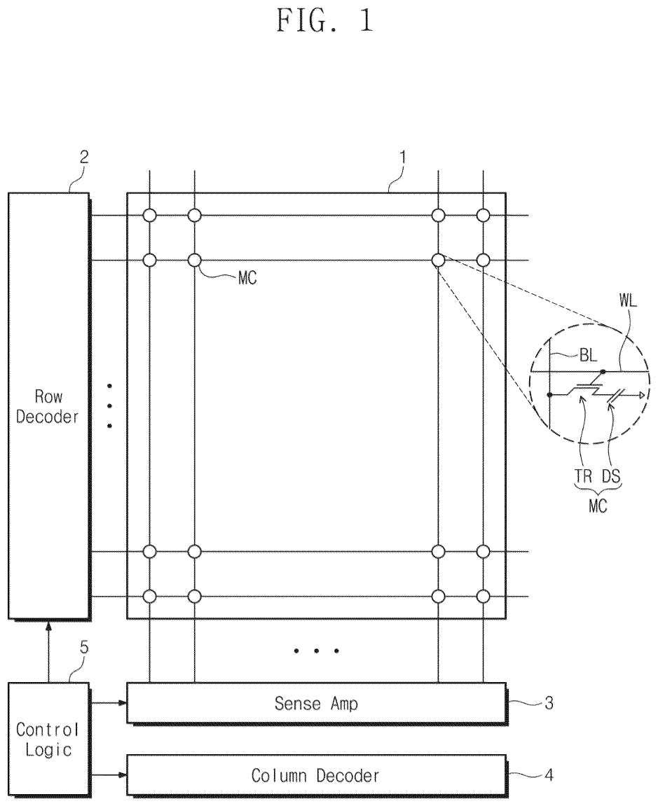

FIG. 1 is a block diagram illustrating a semiconductor memory device according to one or more embodiments of the disclosure.

Referring to FIG. 1, the semiconductor memory device may include a memory cell array 1, a row decoder 2, a sense amplifier 3, a column decoder 4, and a control logic 5.

The memory cell array 1 may include a plurality of memory cells MC two-dimensionally or three-dimensionally arranged. Each of the memory cells MC may be connected between a word line WL and a bit line BL intersecting each other.

The memory cells MC may each include a selection element TR and a data storage element DS and electrically connect the selection element TR and the data storage element DS in series. The selection element TR may be connected between the data storage element DS and the word line WL, and the data storage element DS may be connected to the bit line BL through the selection element TR. The selection element TR may be a field-effect transistor (FET), and the data storage element DS may be implemented as a capacitor, a magnetic tunnel junction pattern, a variable resistor, or the like. For example, the selection element TR may include a transistor, and a gate electrode of the transistor may be connected to the word line WL, and drain/source terminals of the transistor may be respectively connected to the bit line BL and the data storage element DS.

The row decoder 2 may decode an externally input address and select any one of the word lines WL of the memory cell array 1. The address decoded in the row decoder 2 may be provided to a row driver, and the row driver may provide predetermined voltages to a selected word line WL and non-selected word lines WL respectively in response to control by control circuits.

The sense amplifier 3 may sense and amplify a voltage difference between a reference bit line and the bit line BL selected according to an address decoded by the column decoder 4 and output the amplified voltage difference.

The column decoder 4 may provide a data transmission path between the sense amplifier 3 and an external device (e.g., memory controller). The column decoder 4 may decode an externally input address and select any one of the bit lines BL.

The control logic 5 may generate control signals for controlling operations of writing or reading data to or from the memory cell array 1.

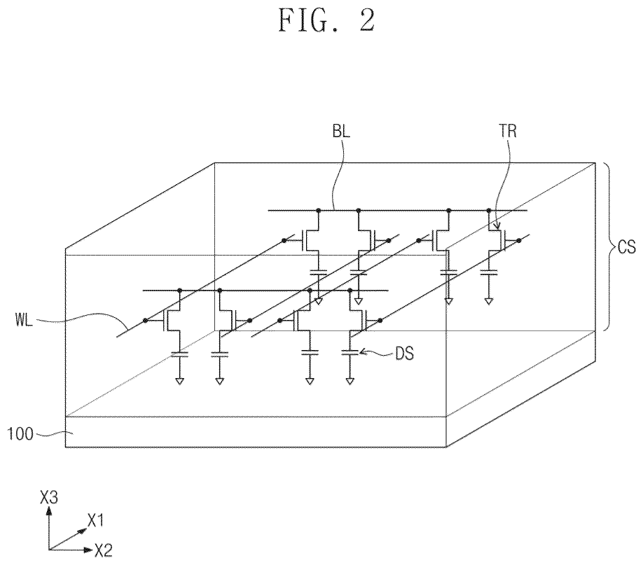

FIG. 2 is a perspective view schematically illustrating a semiconductor memory device according to one or more embodiments of the disclosure.

Referring to FIG. 2, the semiconductor memory device may include a cell array structure on a semiconductor substrate 100. The semiconductor substrate 100 may be a single-crystal silicon substrate or a silicon on insulator (SOI) substrate. The cell array structure CS may include the bit lines BL and the word lines WL and the memory cells MC (FIG. 1) therebetween. The memory cells MC (FIG. 1) may be two-dimensionally or three-dimensionally arranged on a plane extending in first and second directions X1 and X2 intersecting each other. As described above, the memory cells MC (FIG. 1) may each include the selection element TR and the data storage element DS.

According to one or more embodiments, a vertical channel transistor (VCT) may be included as the selection element TR of each memory cell MC (FIG. 1). The vertical channel transistor may refer to a structure in which a channel length extends in a direction (i.e., third direction X3) perpendicular to an upper surface of the semiconductor substrate 100. Furthermore, a capacitor may be provided as the data storage element DS of each memory cell MC (FIG. 1). The data storage element DS may be located between the selection element TR and the semiconductor substrate 100. However, the disclosure is not limited thereto. The semiconductor substrate 100 may be located on the cell array structure CS. In this case, the selection element TR may be interposed between the data storage element DS and the semiconductor substrate 100.

In one or more embodiments of the disclosure, a peripheral circuit structure may be disposed between the semiconductor substrate 100 and the cell array structure CS. The peripheral circuit structure may include the row decoder 2, the sense amplifier 3, the column decoder 4, and the control logic 5 of FIG. 1, etc.

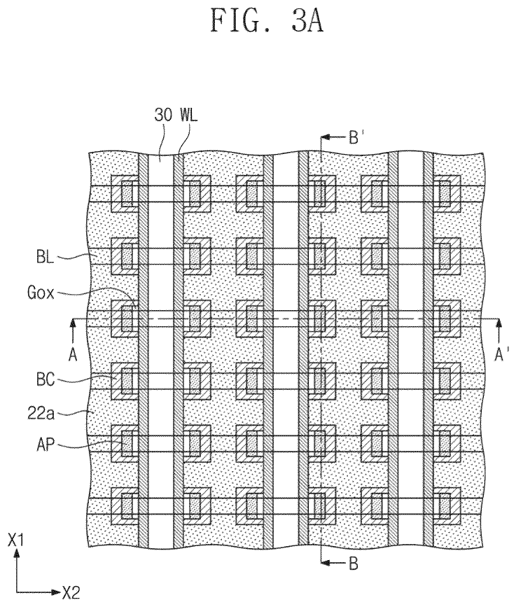

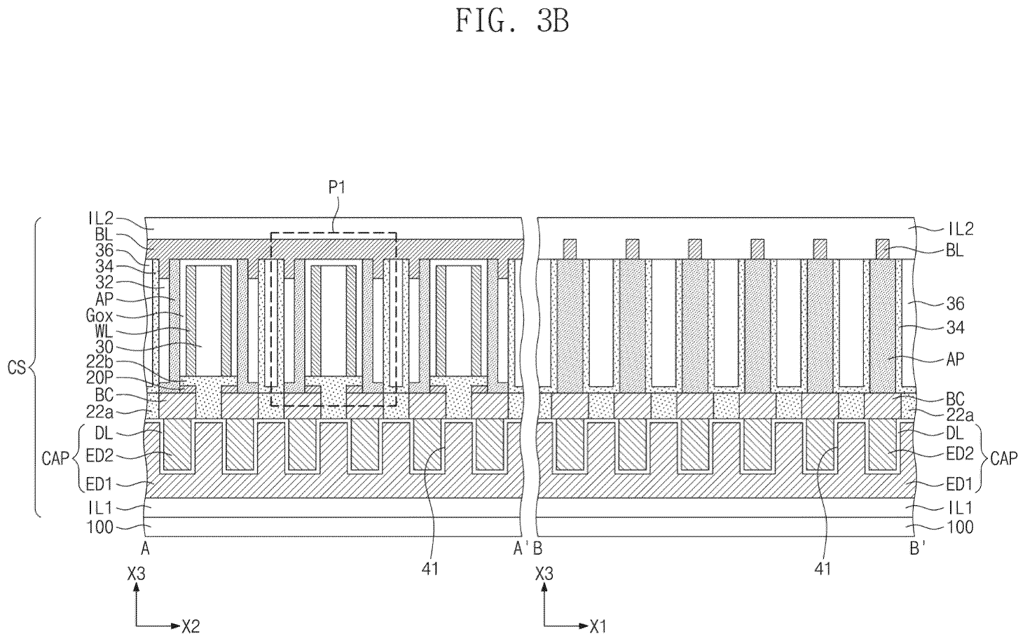

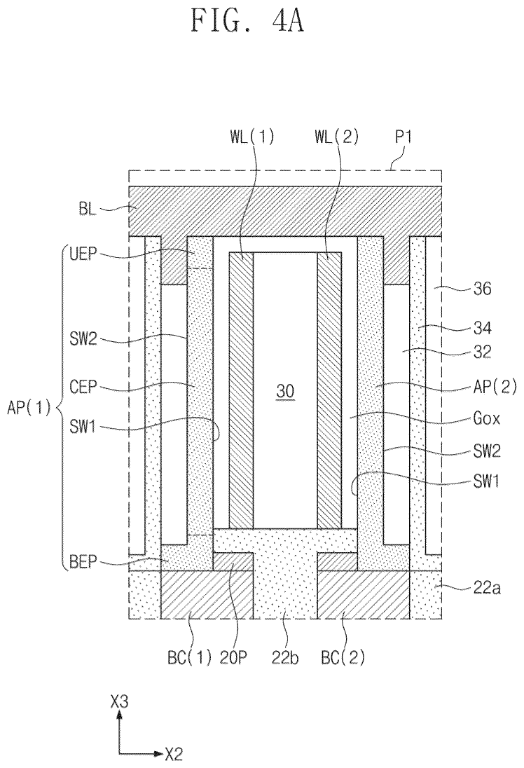

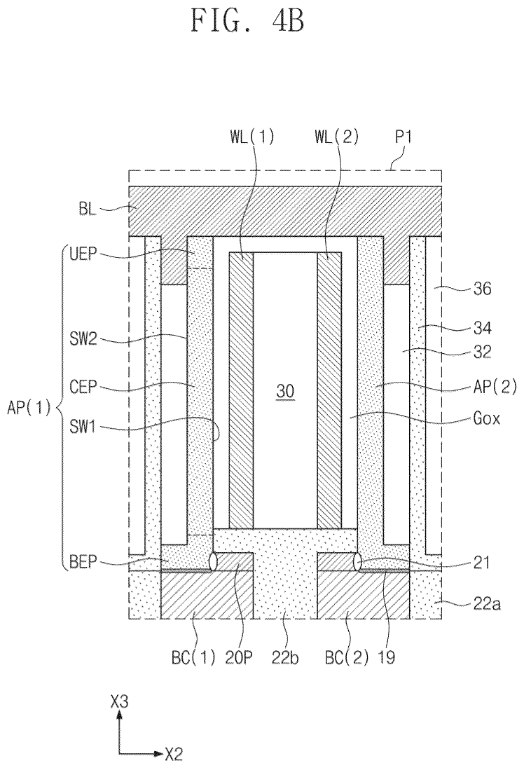

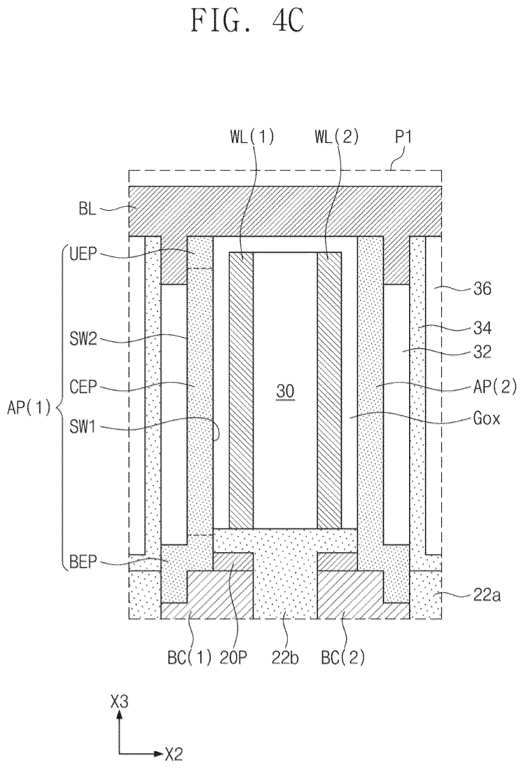

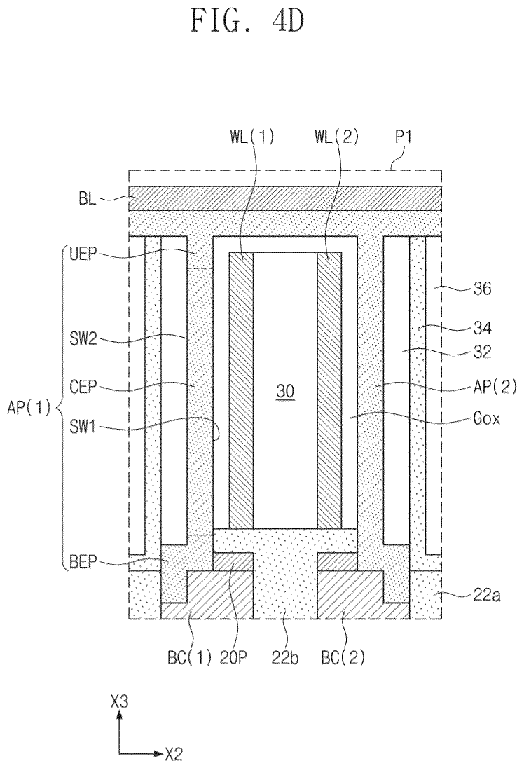

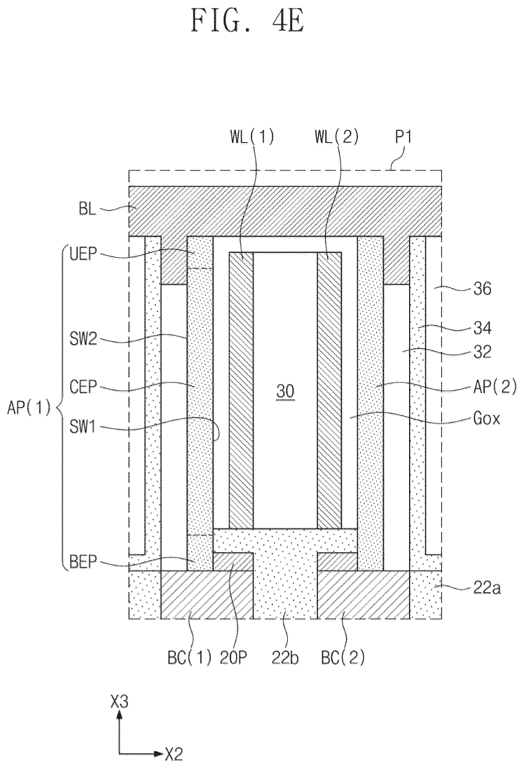

FIG. 3A is a plan view of a semiconductor memory device according to one or more embodiments of the disclosure. FIG. 3B shows cross-sectional views taken along line A-A′ and line B-B′ of FIG. 3A according to one or more embodiments of the disclosure. FIGS. 4A to 4E are enlarged views of portion P1 of FIG. 3B according to one or more embodiments of the disclosure.

Referring to FIGS. 3A, 3B, and 4A, the cell array structure CS is disposed on the semiconductor substrate 100. The cell array structure CS includes a first interlayer insulating layer IL1, a capacitor CAP, storage node contact plugs BC, conductive patterns 20P, active patterns AP, word lines WL, bit lines BL, a second interlayer insulating layer IL2, etc.

The semiconductor substrate 100 may be a single-crystal silicon substrate or a silicon on insulator (SOI) substrate. The above-mentioned peripheral circuits may be formed on the semiconductor substrate 100. The semiconductor substrate 100 may be covered with the first interlayer insulating layer IL1. The first interlayer insulating layer IL1 may be formed as a single-layer or multi-layer structure of at least one of silicon oxide, silicon nitride, silicon oxynitride, or porous insulator.

A plate electrode ED1, a dielectric layer DL, and unit electrodes ED2 may be sequentially stacked on the first interlayer insulating layer IL1. The plate electrode ED1, the dielectric layer DL, and the unit electrodes ED2 may constitute the capacitors CAP. The capacitors CAP may correspond to the data storage element DS of FIGS. 1 and 2.

The plate electrode ED1 may be formed as a single-layer or multi-layer structure of at least one of a titanium nitride layer, tungsten layer, impurity-doped polysilicon layer, or impurity-doped silicon germanium layer. An upper surface of the plate electrode ED 1 may have a surface relief structure. The upper surface of the plate electrode ED1 may include trenches into which the unit electrodes ED2 may be inserted.

The dielectric layer DL may conformally cover the upper surface of the plate electrode ED1. The dielectric layer DL may be formed as, for example, a single layer or multi-layer of a silicon oxide layer or metal oxide layer such as an aluminum oxide layer formed of a material having a higher electric constant than a silicon oxide layer. The unit electrodes ED2 may be arranged on the dielectric layer DL.

The unit electrodes ED2 may be arranged in a matrix form or a form of honeycomb along the first direction X1 and the second direction X2. The unit electrodes ED2 may be arranged at regular intervals. The unit electrodes ED2 may include at least one of impurity-doped polysilicon, metal, metal oxide layer, or metal nitride layer. The unit electrodes ED2 may include a titanium nitride layer. The unit electrodes ED2 may each have a pillar shape or a hollow cup shape. The unit electrode ED2 may also be referred to as a storage node electrode. U pper surfaces of the unit electrodes ED2 may be coplanar with an upper surface of the dielectric layer DL.

The storage node contact plugs BC may be arranged on the unit electrodes ED2 and may be in contact with corresponding unit electrodes ED2. The storage node contact plugs BC may be arranged in a matrix form or a form of honeycomb along the first direction X1 and the second direction X2. The storage node contact plugs BC may be arranged at regular intervals. The storage node contact plugs BC may be formed of a conductive material. For example, the storage node contact plugs BC may be formed of a first metal (e.g., tungsten). The storage node contact plugs BC may include a pair of first and second storage node contact plugs BC(1) and BC(2) adjacent to each other in the second direction X2.

The conductive patterns 20P are arranged on the storage node contact plugs BC, respectively. One conductive pattern 20P may be partially in contact with an upper surface of the storage node contact plug BC disposed under the one conductive pattern 20P. The conductive pattern 20P may be formed of a second metal having second oxidizing power that is higher than a first oxidizing power of the first metal constituting the storage node contact plugs BC. The second metal may be, for example, at least one of tantalum, niobium, or aluminum. In the present disclosure, the wording “high/excellent oxidizing power” may indicate “high/excellent affinity with oxygen atoms” or “better bonding with oxygen atoms”.

First and second separation insulating patterns 22a and 22b may be arranged between the storage node contact plugs BC. The first and second separation insulating patterns 22a and 22b, for example, may be formed as a single-layer or as a multi-layer structure of at least one of silicon oxide, silicon nitride, or silicon oxynitride. The second separation insulating pattern 22b may be disposed between the first and second storage node contact plugs BC(1) and BC(2) adjacent to each other. The second separation insulating pattern 22b may have a T-shaped cross-section. The second separation insulating pattern 22b may extend between the conductive patterns 20P adjacent to each other and cover upper surfaces of the conductive patterns 20P adjacent to each other. Both sidewalls of the second separation insulating pattern 22b may be aligned with sidewalls of the conductive patterns 20P.

An upper portion of the second separation insulating pattern 22b may partially overlap the pair of first and second storage node contact plugs BC(1) and BC(2). In a plan view, the second separation insulating pattern 22b may have a line shape extending in the first direction X1.

The first separation insulating patterns 22a may be arranged outside the pair of first and second storage node contact plugs BC(1) and BC(2) in the second direction X2. The first separation insulating patterns 22a may be arranged between the storage node contact plugs BC in the first direction X1. The first separation insulating patterns 22a may have a rectangular cross-section. Upper surfaces of the first separation insulating patterns 22a may be lower than the upper surface of the second separation insulating pattern 22b.

A mold pattern 30 is disposed on the second separation insulating pattern 22b. The mold pattern 30, for example, may be formed as a single-layer or multi-layer structure of at least one of silicon oxide, silicon nitride, silicon oxynitride, or SiOCH. The mold pattern 30 may have a line shape extending in the first direction X1. A width of the mold pattern 30 in the second direction X2 may be smaller than a width of the second separation insulating pattern 22b in the second direction X2.

Both sidewalls of the mold pattern 30 may be covered with the word lines WL. The word lines WL may include a pair of first and second word lines WL(1) and WL(2) that are adjacent to each other and in contact with one mold pattern (30). The first word line WL(1) may vertically overlap the first storage node contact plug BC(1), and the second word line WL(2) may vertically overlap the second storage node contact plug BC(2). The word lines WL may have a line shape extending in the first direction X1. The word lines WL may include impurity-doped polysilicon or metal such as tungsten and aluminum.

A gate insulating layer Gox may cover outer sidewalls of the pair of first and second word lines WL(1) and WL(2) and an upper surface of the mold pattern 30. The gate insulating layer Gox may be formed of a silicon oxide layer, a silicon oxynitride layer, a high dielectric layer with a higher dielectric constant than silicon oxide layer, an aluminum oxide, or a combination thereof. A sidewall of the gate insulating layer Gox may be vertically aligned with an upper sidewall of the second separation insulating pattern 22b. The gate insulating layer Gox may block (prevent) hydrogen that may be included in the mold pattern (30) from diffusing to the active pattern AP. Accordingly, deterioration of the active pattern AP may be prevented.

Both sidewalls of the gate insulating layer Gox may be covered with the active patterns AP spaced apart from each other. The active patterns AP may be formed of an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof.

Referring to FIG. 4A, the active patterns A P may include a pair of first and second active patterns AP(1) and AP(2) adjacent to each other in the second direction X2 and covering both sidewalls of one gate insulating layer Gox. The first and second active patterns AP(1) and AP(2) may each have an L-shaped cross-section or rotated L-shaped cross-section. The first and second active patterns AP(1) and AP(2) may be mirror symmetrical to each other. The first and second active patterns AP(1) and AP(2) may extend downward and at least partially cover an upper sidewall of the second separation insulating pattern 22b, a sidewall of the conductive pattern 20P, and upper surfaces of the first and second storage node contact plugs BC(1) and BC(2).

The active patterns AP may each have a channel portion CEP, a first end portion BEP, and a second end portion UEP. The channel portion CEP may be located between the first end portion BEP and the second end portion UEP and may horizontally overlap the word line WL. The first end portion BEP may be located under the channel portion CEP and adjacent to the storage node contact plug BC. The second end portion UEP may be located on the channel portion CEP and adjacent to the bit line BL. The first end portion BEP may have a wider width than the second end portion UEP in the second direction X2. The first end portion BEP may be in contact with both the upper surface of the storage node contact plug BC and a side surface of the conductive pattern 20P. That is, the conductive pattern 20P may be in contact with both a sidewall of the first end portion BEP of the active pattern AP and the upper surface of the storage node contact plug BC. Oxygen content (or concentration) per unit volume in the channel portion CEP may be higher than oxygen content (or concentration) per unit volume in the first end portion BEP.

The channel portion CEP of the active pattern AP may correspond to a channel of the selection element TR of FIGS. 1 and 2, i.e., a vertical channel transistor. A portion of the word line WL adjacent to the channel portion CEP may correspond to a gate of the vertical channel transistor.

The active patterns AP may each have a first sidewall SW1 and a second sidewall SW2 opposite to each other. The first sidewall SW1 may be in contact with the gate insulating layer Gox. The second sidewall SW2 may be sequentially covered with first to third insulating layers 32, 34, and 36. The first end portion BEP of the active pattern AP may be interposed between the first insulating layer 32 and the storage node contact plug BC.

The first to third insulating layers 32, 34, and 36 may include different materials. Alternatively, an etch rate of the first insulating layer 32 may be higher than etch rates of the second insulating layer 34 and the third insulating layer 36. In another example, the first insulating layer 32 may have a lower density than the second insulating layer 34 and the third insulating layer 36. In another example, the third insulating layer 36 may include hydrogen, and the second insulating layer 34 may block the hydrogen included in the third insulating layer 36 from diffusing to the active pattern AP. Accordingly, the active pattern AP may be prevented from being deteriorated. In an example, the first insulating layer 32 may be formed of silicon oxide. The second insulating layer 34 may be formed of aluminum oxide. The third insulating layer 36 may be formed of SiOCH.

A sidewall of the first insulating layer 32 may be vertically aligned with a sidewall of the first end portion of the active pattern AP. The second insulating layer 34 may have a U-shaped cross-section. The second insulating layer 34 may be in contact with an upper surface of the first separation insulating pattern 22a. The third insulating layer 36 may be located in the second insulating layer 34 and may fill a spaced proved by the second insulating layer 34. A level of an upper end of the first insulating layer 32 may be lower than upper surfaces of the second insulating layer 34 and the third insulating layer 36.

The bit line BL may traverse the active patterns AP in the second direction X2. The bit line BL may be in contact with upper surfaces and sidewalls of the second end portions UEP of the active patterns AP. The bit line BL may be provided in plurality. The bit lines BL may extend in the second direction X2 and may be spaced apart from each other in the first direction X1. The bit line BL may be formed of a conductive material and may include, for example, a single-layer or multi-layer structure of at least one of impurity-doped polysilicon, conductive metal nitride (e.g., titanium nitride, tantalum nitride, etc.), or metal (e.g., tungsten, titanium, tantalum, etc.).

The second interlayer insulating layer IL2 may be disposed on the bit lines BL. The second interlayer insulating layer IL2 may be formed as a single-layer or multi-layer structure of at least one of silicon oxide, silicon nitride, silicon oxynitride, or porous insulator.

In another example, referring to FIG. 4B, a first metal oxide layer 19 may be interposed between the active pattern AP and the storage node contact plug BC. The first metal oxide layer 19 may be formed of oxide of the first metal constituting the storage node contact plug BC. The first metal oxide layer 19 may be excluded between the active pattern AP and the storage node contact plug BC.

A second metal oxide layer 21 may be interposed between the active pattern AP and the conductive pattern 20P. The second metal oxide layer 21 may be formed of oxide of the second metal constituting the conductive pattern 20P. A thickness of the second metal oxide layer 21 may be larger than a thickness of the first metal oxide layer 19.

In the semiconductor memory device according to one or more embodiments of the disclosure, the first end portion BEP of the active pattern AP may be in contact with both the storage node contact plug BC and the conductive pattern 20P. The second metal constituting the conductive pattern 20P may have a second oxidizing power higher than a first oxidizing power of the first metal constituting the storage node contact plug BC. Therefore, oxygen included in the active pattern AP may better bond with the second metal than with the first metal. Therefore, the second metal oxide layer 21 between the conductive pattern 20P and the active pattern AP may be more smoothly formed than the first metal oxide layer 19 between the storage node contact plug BC and the active pattern AP. Accordingly, since the first metal oxide layer 19 that is highly insulative is formed to be thin or is not formed, contact resistance between the active pattern AP and the storage node contact plug BC may reduce. Therefore, an amount of turn-on current may increase in the semiconductor memory device, thus reducing malfunction and improving reliability.

In another example, referring to FIG. 4C, the first end portion BEP of the active pattern AP may extend downward and may be in contact with a sidewall of the storage node contact plug BC.

In another example, referring to FIG. 4D, the second end portion UEP of the active pattern AP may extend upward and may be interposed between the bit line BL and the mold pattern 30 and between the bit line BL and the first to third insulating layers 32, 34, and 36.

In another example, referring to FIG. 4E, the active pattern AP may have an I-shaped form. The first end portion BEP of the active pattern AP is not interposed between the first insulating layer 32 and the storage node contact plug BC. The first insulating layer 32 may be in contact with an upper surface of the storage node contact plug BC. Other configurations may be the same as/similar to those described above.

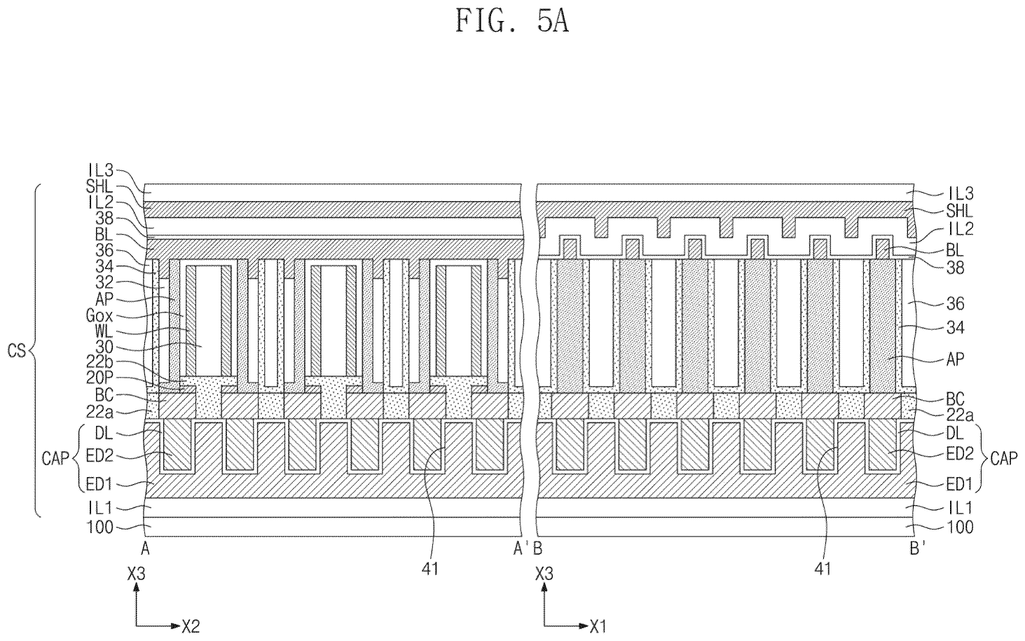

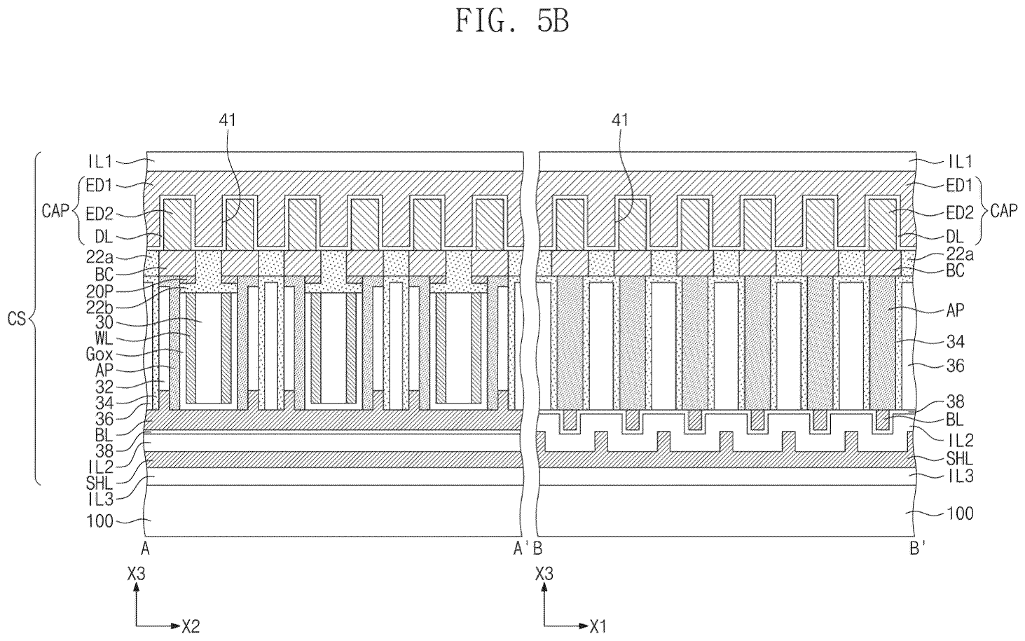

FIGS. 5A and 5B shows cross-sectional views taken along line A-A′ and line B-B′ of FIG. 3A according to one or more embodiments of the disclosure.

Referring to FIG. 5A, in the semiconductor memory device according to the present example, the cell array structure CS may further include a protective layer 38, a shield line SHL, and a third interlayer insulating layer IL3 in addition to the structure of FIG. 3. In detail, the protective layer 38 may be interposed between the second interlayer insulating layer IL2 and the bit lines BL. The protective layer 38 may be formed of a material having etch selectivity with respect to the second interlayer insulating layer IL2. The protective layer 38 may block hydrogen from diffusing. The protective layer 38 may be formed of, for example, silicon nitride or aluminum oxide. An upper surface of the second interlayer insulating layer IL2 may have a surface relief structure. The shield line SHL and the third interlayer insulating layer IL3 may be sequentially arranged on the second interlayer insulating layer IL2. A portion of the shield line SHL may be inserted between the bit lines BL. The shield line SHL may be formed of a conductive material and may include, for example, a single-layer or multi-layer structure of at least one of impurity-doped polysilicon, conductive metal nitride (e.g., titanium nitride, tantalum nitride, etc.), or metal (e.g., tungsten, titanium, tantalum, etc.). The third interlayer insulating layer IL3 may be formed as a single layer or multi-layer structure of at least one of silicon oxide, silicon nitride, silicon oxynitride, or porous insulator. Other configurations may be the same as/similar to those described above.

Referring to FIG. 5B, the cell array structure CS is disposed on the semiconductor substrate 100. The cell array structure CS of FIG. 5B may have a structure in which the cell array structure CS of FIG. 5A is turned upside down. The semiconductor substrate 100 may be in contact with the third interlayer insulating layer IL3. The shield line SHL, the second interlayer insulating layer IL2, the bit lines BL, the active patterns AP, the storage node contact plugs BC, the capacitors CAP, and the first interlayer insulating layer IL1 may be sequentially arranged on the the third interlayer insulating layer IL3. The word lines WL may be adjacent to the first sidewalls SW1 (FIG. 4A) of the active patterns AP. Other configurations may be the same as/similar to those described above.

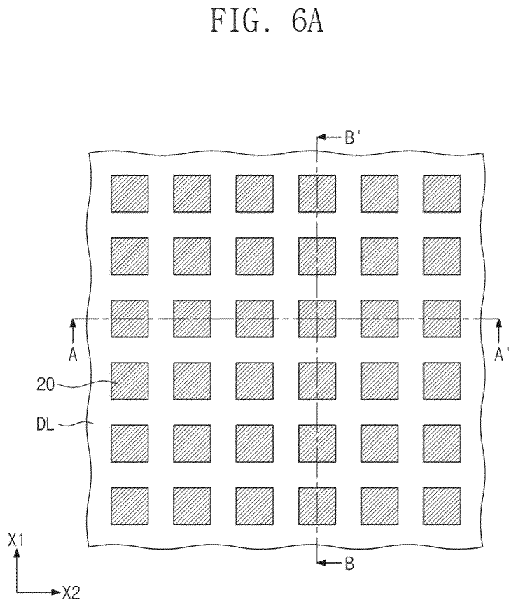

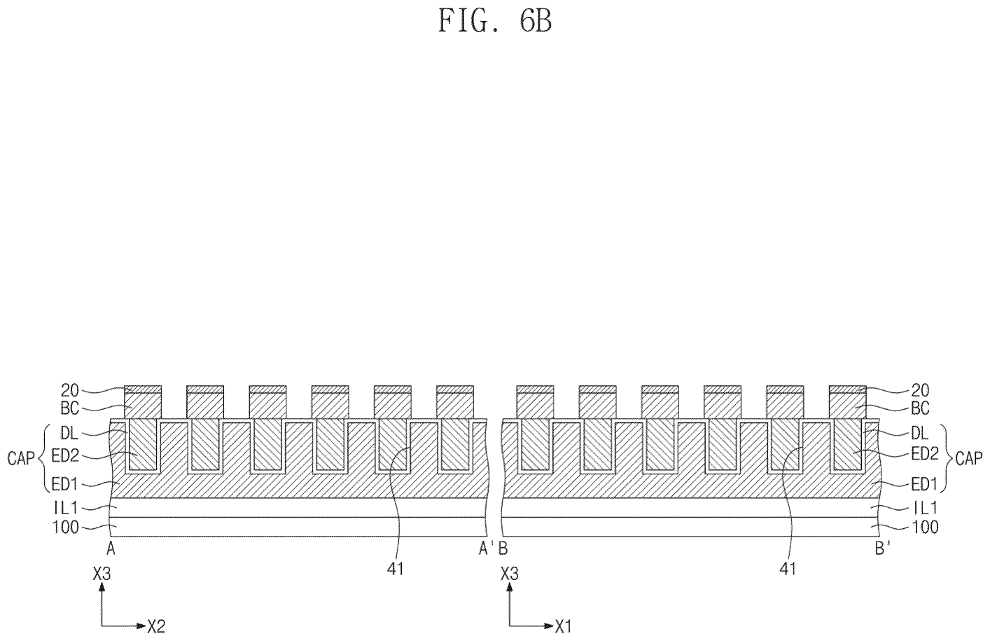

FIGS. 6A to 13A are plan views sequentially illustrating a process of manufacturing the semiconductor memory device of FIG. 3A. FIGS. 6B to 13B, 14, and 15 are cross-sectional views sequentially illustrating a process of manufacturing the semiconductor memory device of FIG. 3B. FIGS. 6B to 13B may correspond to cross-sections taken along line A-A′ and line B-B′ of FIGS. 6A to 13A.

Referring to FIGS. 6A and 6B, the first interlayer insulating layer IL1 is stacked on the semiconductor substrate 100. The plate electrode ED1 is formed on the first interlayer insulating layer IL1. A plurality of trenches 41 are formed by etching the plate electrode ED1. The dielectric layer DL is conformally formed on the plate electrode ED1. After filling the trenches 41 by stacking a unit electrode layer on the dielectric layer DL, a blanket anisotropic etching process or a chemical mechanical polishing (CMP) process is performed to form the unit electrodes ED2 in the trenches 41 and expose the dielectric layer DL. As a result, the capacitors CAP may be formed. The storage node contact plugs BC and preliminary conductive patterns 20 may be formed and the dielectric layer DL may be exposed by sequentially stacking a storage node contact layer and a conductive layer on the capacitors CAP and patterning the same. The storage node contact plugs BC and the preliminary conductive patterns 20 may vertically overlap the unit electrodes ED2. The storage node contact plugs BC, the preliminary conductive patterns 20, and the unit electrodes ED2 may be two-dimensionally arranged in the first and second directions X1 and X2.

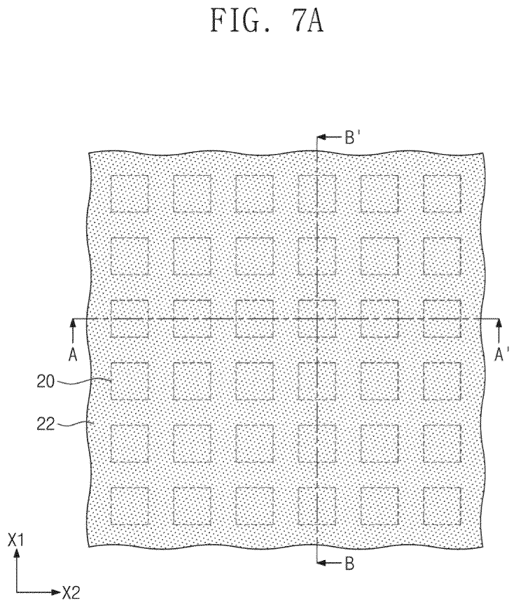

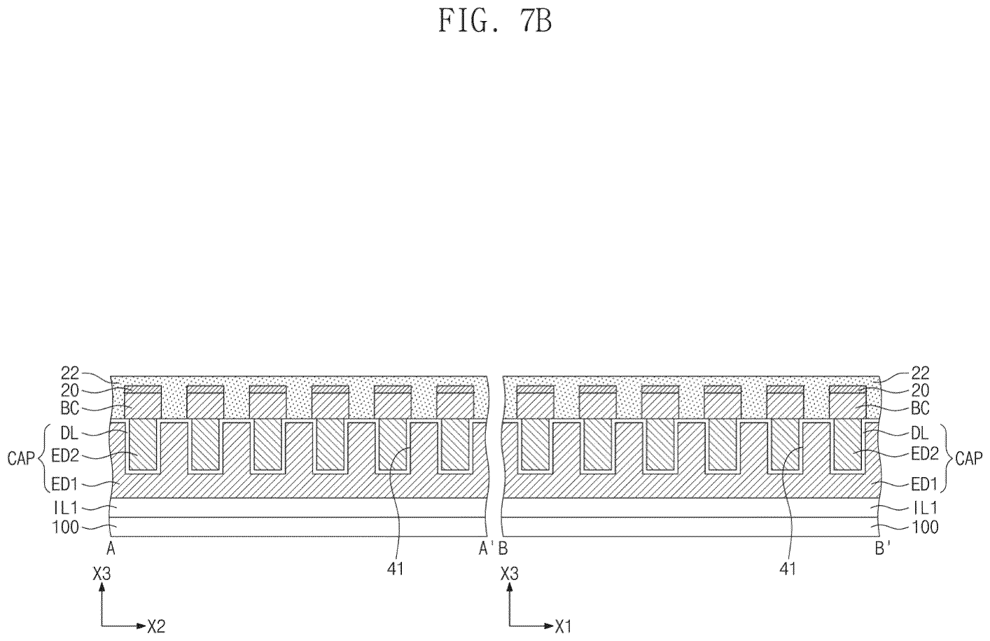

Referring to FIGS. 7A and 7B, an isolation insulating layer 22 is formed on a front side of the semiconductor substrate 100 and covers the dielectric layer DL, the storage node contact plugs BC, and the preliminary conductive patterns 20. The isolation insulating layer 22 may be formed of, for example, silicon nitride.

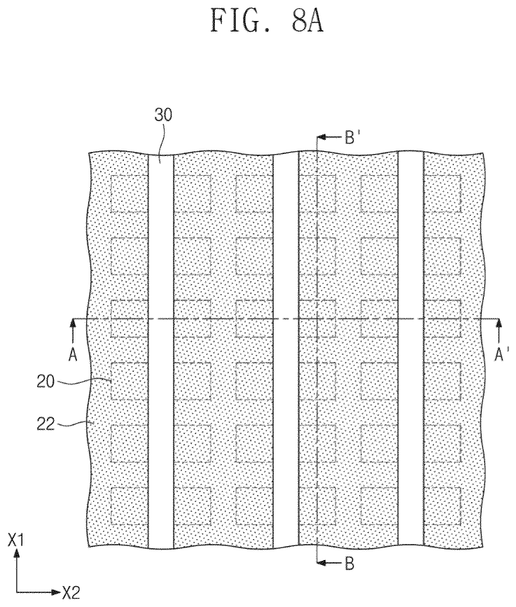

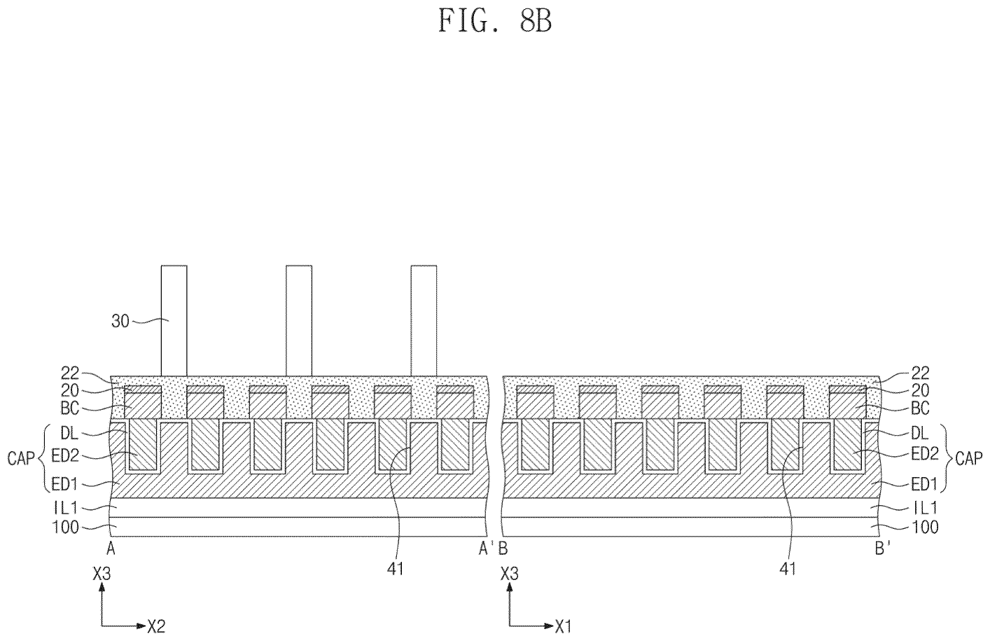

Referring to FIGS. 8A and 8B, the mold patterns 30 are formed on the isolation insulating layer 22. The mold pattern 30 may be formed of a porous low-dielectric material such as SiOCH. The mold pattern 30 may be formed in a line shape extending in the first direction X1. The mold pattern 30 may overlap the isolation insulating layer 22 between two storage node contact plugs BC.

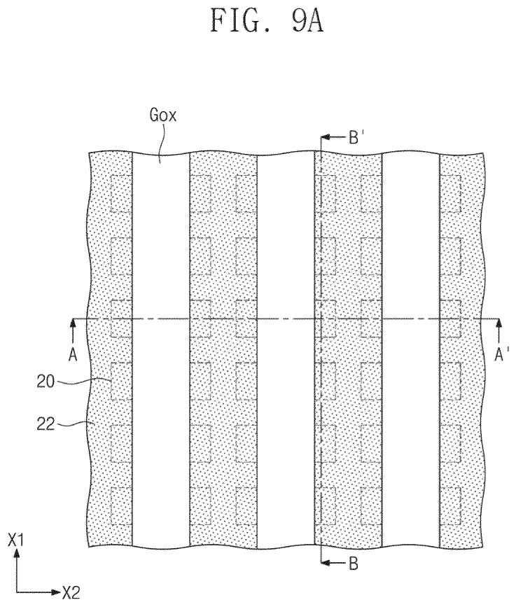

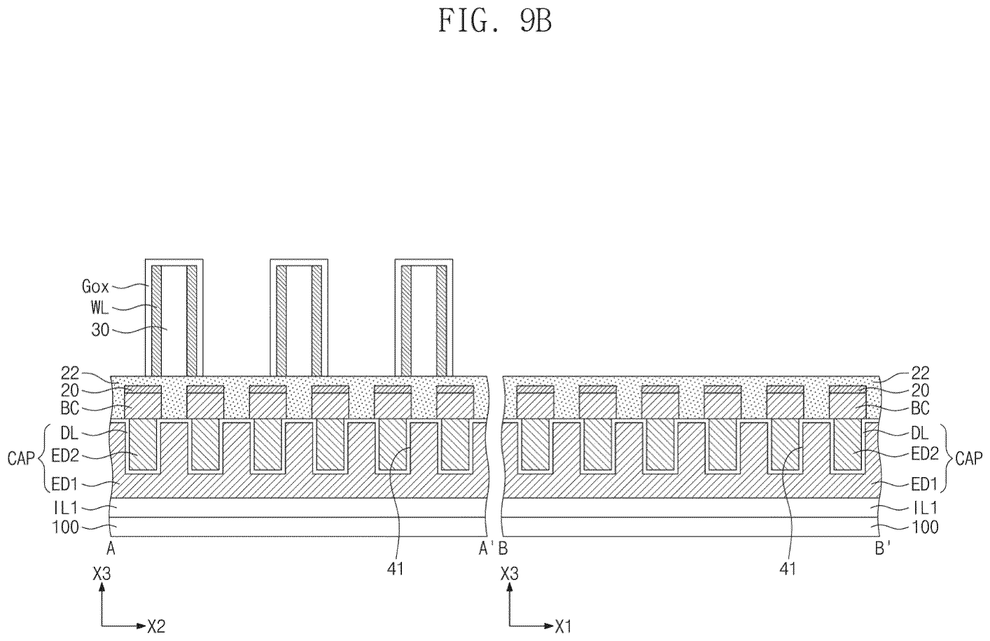

Referring to FIGS. 9A and 9B, an anisotropic etching process may be performed after conformally forming a word line layer on the mold pattern 30 to form the word lines WL covering both sidewalls of the mold pattern 30 and expose an upper surface of the mold pattern 30 and an upper surface of the isolation insulating layer 22. Furthermore, the gate insulating layer Gox covering the word lines WL and the mold pattern 30 is formed.

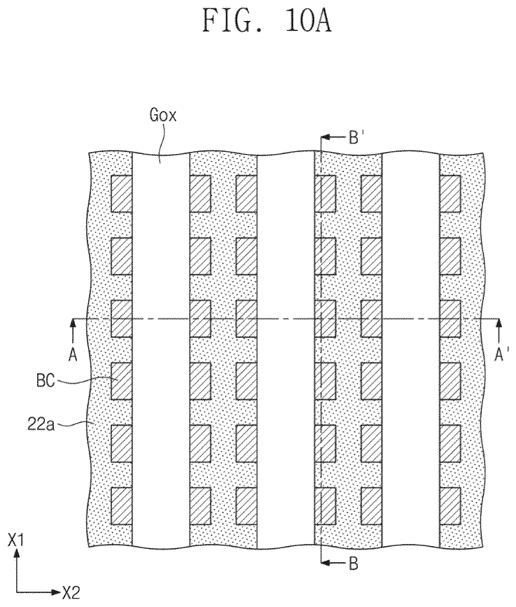

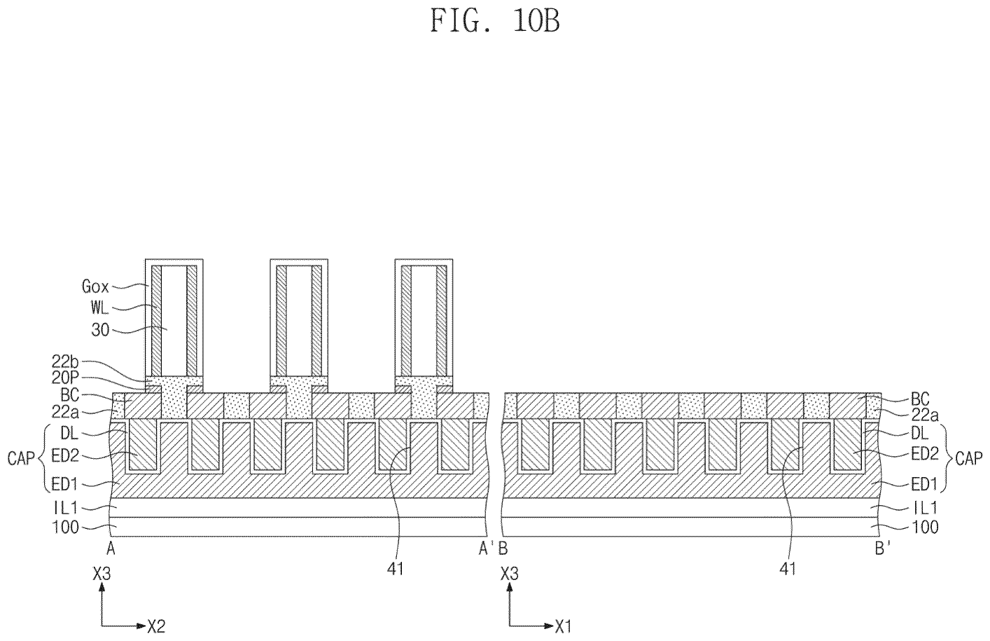

Referring to FIGS. 10A and 10B, a first mask pattern may be formed on the gate insulating layer Gox. The first mask pattern may cover the mold pattern 30, the word lines WL, and the gate insulating layer Gox and expose an upper surface of the isolation insulating layer 22 located beside the foregoing. An upper surface of the storage node contact plug BC may be exposed and, at the same time, the conductive pattern 20P and the first and second separation insulating patterns 22a and 22b may be formed by etching the isolation insulating layer 22 and the preliminary conductive pattern 20 using the first mask pattern as an etching mask. Thereafter, the first mask pattern is removed.

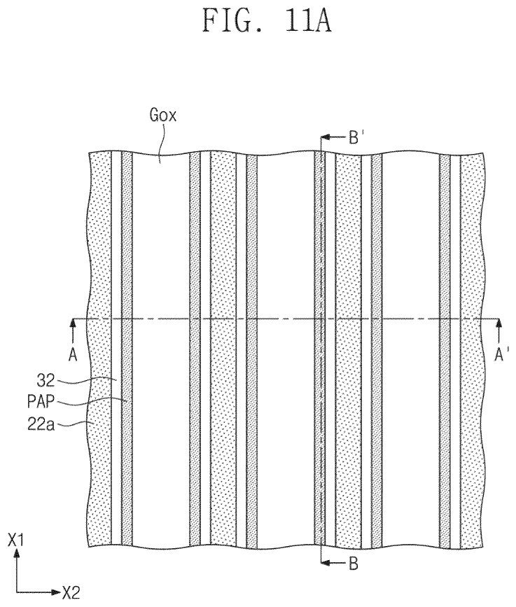

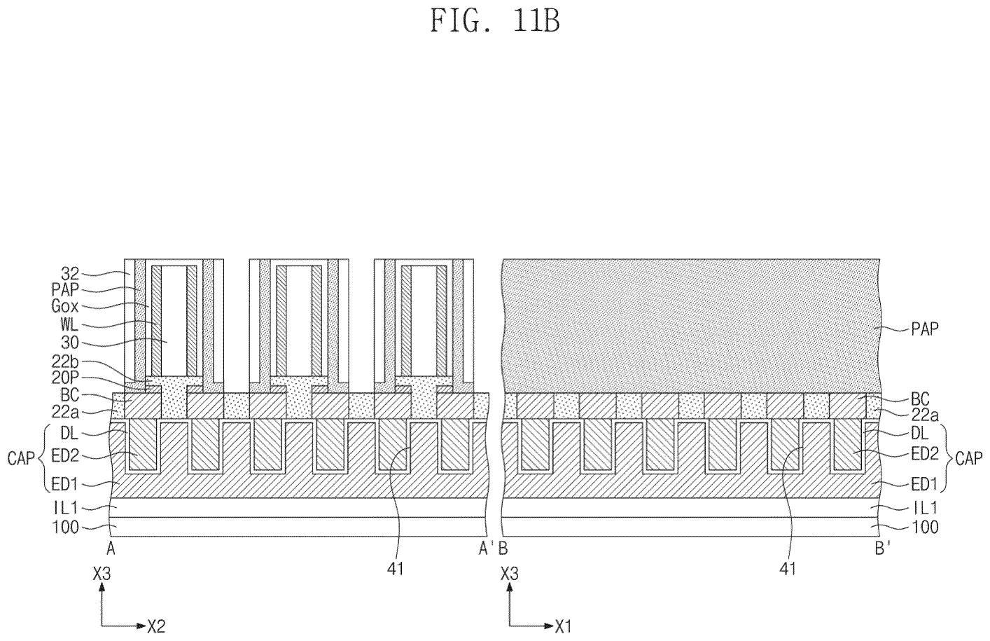

Referring to FIGS. 11A and 11B, an active layer is conformally formed on the gate insulating layer Gox and the first and second separation insulating patterns 22a and 22b. The first insulating layer 32 covering a side surface of the mold pattern 30 is formed. An anisotropic etching process is performed on the active layer to form a preliminary active pattern PAP and expose upper surfaces of the first separation insulating patterns 22a. The preliminary active pattern PAP may have a line shape extending in the first direction X1.

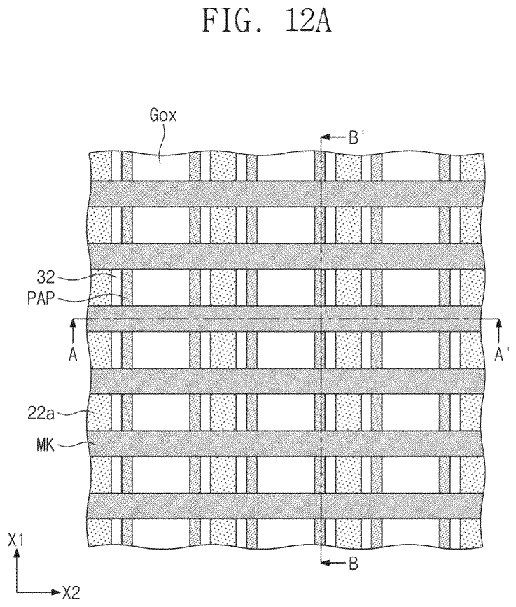

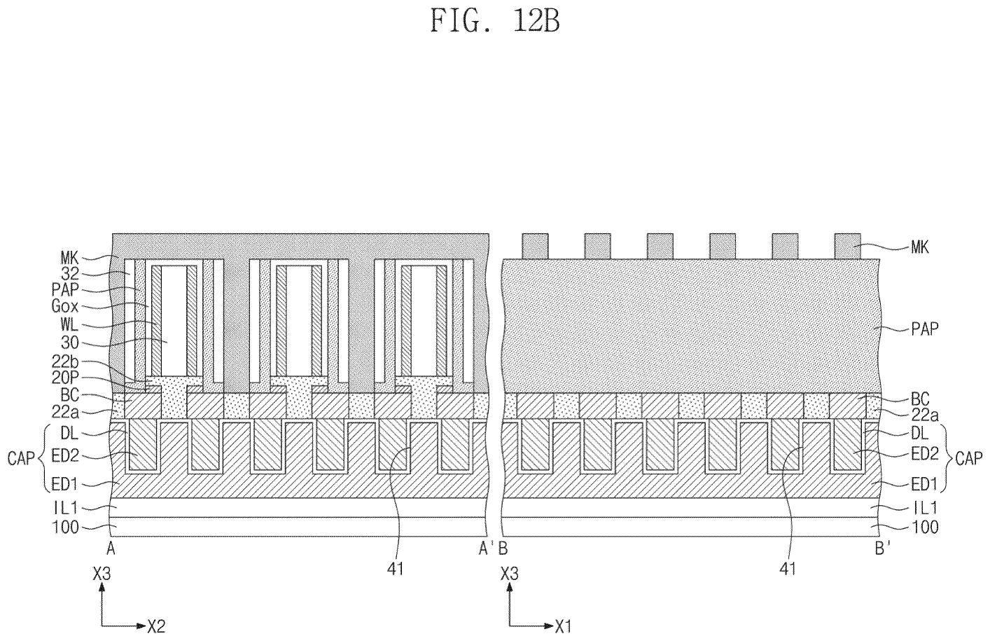

Referring to FIGS. 12A and 12B, a second mask pattern MK is formed on the preliminary active pattern PAP. The second mask pattern MK may overlap the storage node contact plugs BC. The second mask pattern MK may expose the preliminary active pattern PAP vertically overlapping the first separation insulating patterns 22a between the storage node contact plugs BC. In a plan view, the second mask pattern MK may have a line shape extending in the second direction X2. A Iternatively, the second mask pattern MK may have a mesh shape including openings that expose portions of the preliminary active pattern PAP.

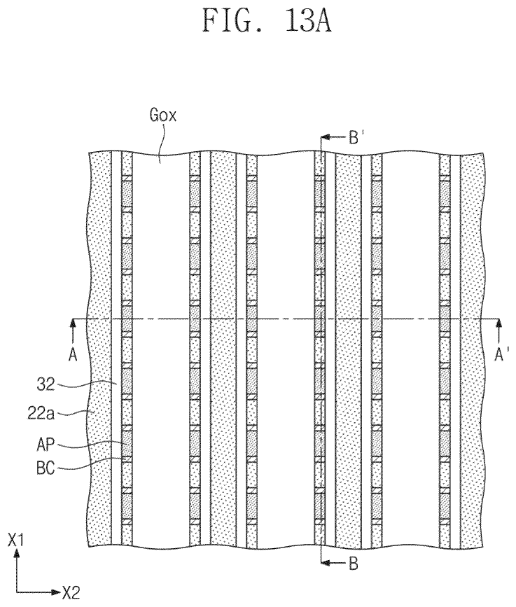

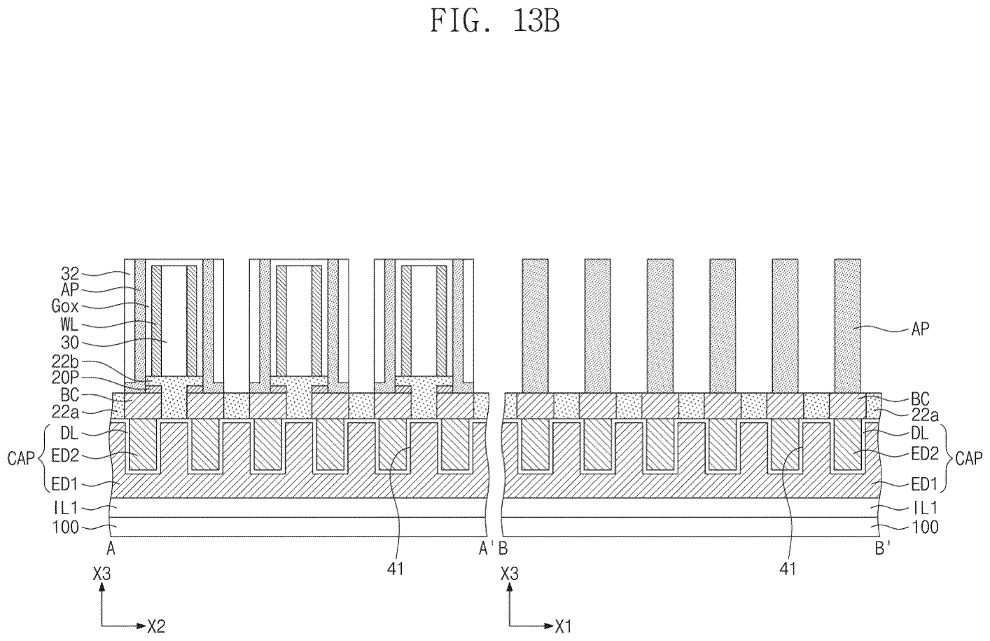

Referring to FIGS. 12A, 12B, 13A, and 13B, the active patterns AP spaced apart from each other are formed and upper surfaces of the first separation insulating patterns 22a are exposed by partially removing the preliminary active pattern PAP using the second mask pattern MK as an etching mask. The active patterns AP may be formed overlapping the storage node contact plugs BC, respectively. Thereafter, the second mask pattern MK is removed. Furthermore, an In-Fab annealing process may be performed. Due to the In-Fab annealing process, oxygen atoms included in the first insulating layer 32 may diffuse into the active patterns AP, and thus oxygen atom content in the channel regions CEP (FIG. 4A) of the active patterns AP may increase.

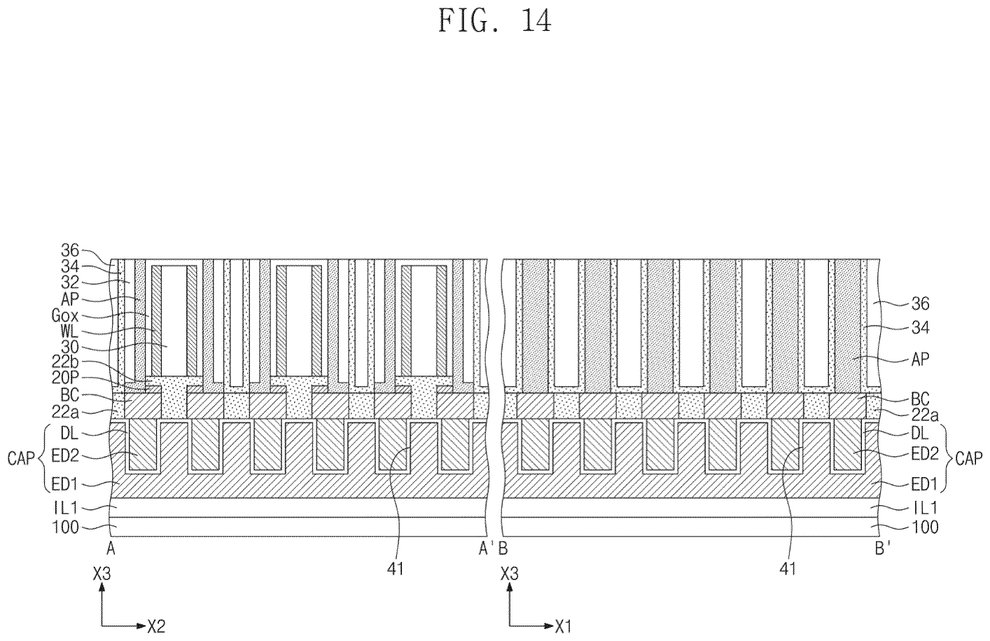

Referring to FIG. 14, the second insulating layer 34 is conformally formed on the front side of the semiconductor substrate 100. Furthermore, the third insulating layer 36 may be formed on the second insulating layer 34, filling a space between the active patterns AP. Upper surfaces of the gate insulating layer Gox, the active patterns AP, and the first insulating layer 32 may be exposed by performing a CMP process on the second insulating layer 34 and the third insulating layer 36.

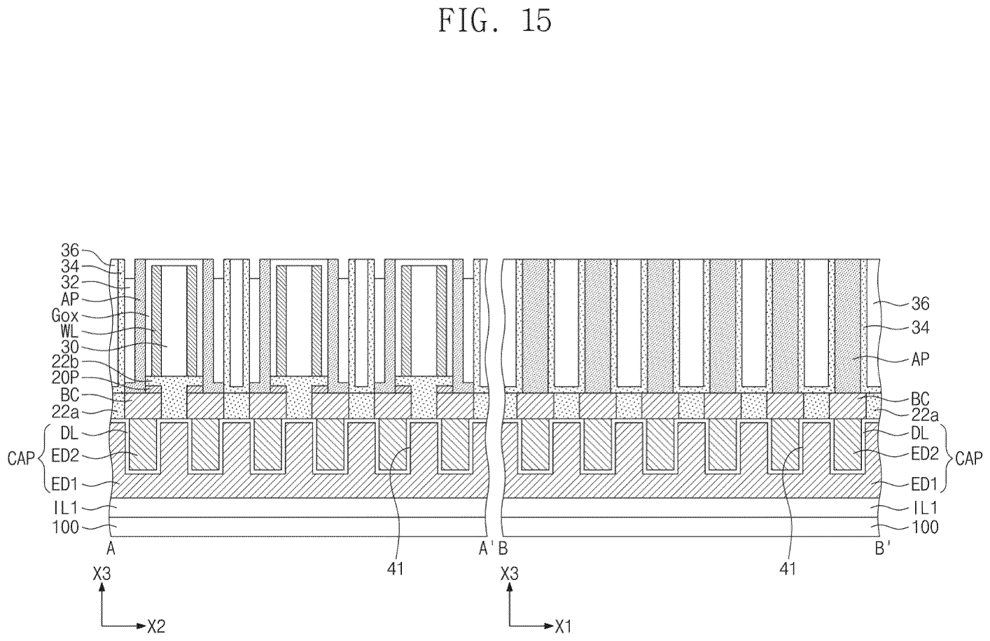

Referring to FIG. 15, upper sidewalls of the active patterns AP and the second insulating layer 34 are exposed by partially removing the first insulating layer 32. Subsequently, referring to FIGS. 3A and 3B, the bit lines BL are formed by stacking a bit line layer on the first to third insulating layers 32, 34, and 36, the active patterns AP, and the gate insulating layer Gox and performing etching thereon. Thereafter, the second interlayer insulating layer IL2 covering the bit lines BL is formed. As a result, the cell array structure CS of FIGS. 3A and 3B may be formed.

According to one or more embodiments of the disclosure, a first end portion of an active pattern is in contact with both a storage node contact plug and a conductive pattern, and the conductive pattern is formed of second metal having a second oxidizing power higher than a first oxidizing power of the first metal constituting the storage node contact plug, and thus contact resistance between the storage node contact plug and the active pattern may reduce. Therefore, the amount of turn-on current may increase in a semiconductor memory device, thus reducing malfunction and improving reliability of the semiconductor memory device. As a result, a semiconductor memory device with improved electrical characteristics and integration density may be provided.

Although one or more embodiments of the present disclosure have been described with reference to the accompanying drawings, those of ordinary skill in the art may understand that the present disclosure can be carried out in other specific forms without changing the technical concept or essential features. Therefore, the above embodiments should be considered illustrative and should not be construed as limiting. The embodiments of FIGS. 1 to 5B may be combined with each other.

What is claimed is:

1. A semiconductor memory device comprising:
a substrate;
an active pattern perpendicular to an upper surface of the substrate, the active pattern comprising a first end portion, a second end portion, a first side surface, and a second side surface, the first end portion being opposite to the second end portion, the first side surface being opposite to the second side surface, and the first side surface and the second side surface connecting the first end portion to the second end portion;
a word line adjacent to the first side surface of the active pattern and extending in a first direction parallel with the upper surface of the substrate;
a storage node contact plug in contact with the first end portion of the active pattern;
a conductive pattern in contact with both the first end portion and the storage node contact plug; and
a bit line in contact with the second end portion of the active pattern,
wherein the storage node contact plug comprises a first metal having a first oxidizing power, and
wherein the conductive pattern comprises a second metal having a second oxidizing power that is higher than the first oxidizing power of the first metal.

2. The semiconductor memory device of claim 1,
wherein the first metal comprises tungsten, and
wherein the second metal comprises at least one of tantalum, niobium, or aluminum.

3. The semiconductor memory device of claim 1,
wherein the bit line extends in a second direction that intersects the first direction and is parallel with the upper surface of the substrate,
wherein the active pattern comprises a first width in the second direction,
wherein the storage node contact plug comprises a second width in the second direction, wherein the second width is larger than the first width, and
wherein the conductive pattern is between a lower surface of the word line and an upper surface of the storage node contact plug.

4. The semiconductor memory device of claim 1, wherein a width of the first end portion is larger than a width of the second end portion.

5. The semiconductor memory device of claim 1, further comprising:
a first metal oxide layer between the storage node contact plug and the active pattern, wherein the first metal oxide layer comprises the first metal; and
a second metal oxide layer between the conductive pattern and the active pattern, wherein the second metal oxide layer comprises the second metal.

6. The semiconductor memory device of claim 1, wherein the first end portion extends downward and is at least partially on a side surface of the storage node contact plug.

7. The semiconductor memory device of claim 1, wherein a portion of the bit line is on at least a portion of the second side surface.

8. The semiconductor memory device of claim 1,
wherein the active pattern comprises an oxide semiconductor, and
wherein an oxygen concentration in a center of the active pattern is higher than an oxygen concentration in the first end portion.

9. The semiconductor memory device of claim 1, further comprising:
a first insulating layer, a second insulating layer, and a third insulating layer sequentially arranged on the second side surface of the active pattern,
wherein the third insulating layer comprises hydrogen, and
wherein the second insulating layer prevents penetration of the hydrogen of the third insulating layer.

10. A semiconductor memory device comprising:
a substrate;
a first active pattern and a second active pattern, the first and the second active patterns being perpendicular to an upper surface of the substrate and the first active pattern being spaced apart from the second active pattern in a first direction;
a mold pattern between the first and the second active patterns;
a first word line between the mold pattern and the first active pattern;
a second word line between the mold pattern and the second active pattern;
a gate insulating layer between the first active pattern and the first word line and between the second active pattern and the second word line, wherein the gate insulating layer is on an upper surface of the mold pattern;
storage node contact plugs that are respectively in contact with lower portions of the first and the second active patterns and which at least partially overlap the first and the second word lines;
a bit line connecting upper portions of the first and the second active patterns;
a separation insulating pattern between the storage node contact plugs and at least partially overlapping the mold pattern, wherein a portion of the separation insulating pattern is between the first and the second word lines and the storage node contact plugs; and
conductive patterns between the separation insulating pattern and the storage node contact plugs, wherein the conductive patterns are in contact with the first and the second active patterns,
wherein the storage node contact plugs comprise a first metal, and
wherein the conductive patterns comprise a second metal different from the first metal.

11. The semiconductor memory device of claim 10, wherein the second metal has a second oxidizing power that is higher than a first oxidizing power of the first metal.

12. The semiconductor memory device of claim 11,
wherein the first metal comprises tungsten, and
the second metal comprises at least one of tantalum, niobium, or aluminum.

13. The semiconductor memory device of claim 10,
wherein the first and the second active patterns are formed of an oxide semiconductor, and
wherein an oxygen concentration in a center of each of the first and the second active patterns is higher than an oxygen concentration in the lower portion of each of the first and the second active patterns.

14. The semiconductor memory device of claim 10,
wherein the first active pattern comprises a first side surface not covered with the gate insulating layer,
wherein the semiconductor memory device further comprises a first insulating layer, a second insulating layer, and a third insulating layer sequentially arranged on the first side surface,
wherein the third insulating layer comprises hydrogen, and
wherein the second insulating layer prevents penetration of the hydrogen of the third insulating layer.

15. The semiconductor memory device of claim 10, wherein a portion of the bit line is on upper side surfaces of the first and the second active patterns.

16. A semiconductor memory device comprising:
a substrate;
an active pattern perpendicular to an upper surface of the substrate, the active pattern comprising a first side surface and a second side surface, the first side surface being opposite to the second side surface;
a storage node contact plug in contact with a lower surface of the active pattern;
a conductive pattern in contact with a lower portion of the first side surface of the active pattern and an upper surface of the storage node contact plug;
a bit line in contact with an upper surface of the active pattern;
a word line on the conductive pattern and adjacent to the first side surface of the active pattern; and
a first insulating layer, a second insulating layer, and a third insulating layer sequentially arranged on the second side surface of the active pattern,
wherein the third insulating layer comprises hydrogen, and
wherein the second insulating layer prevents penetration of the hydrogen of the third insulating layer.

17. The semiconductor memory device of claim 16,
wherein the first and the second active patterns comprise an oxide semiconductor, and
wherein the conductive pattern comprises at least one of tantalum, niobium, or aluminum.

18. The semiconductor memory device of claim 17, wherein the storage node contact plug comprises tungsten.

19. The semiconductor memory device of claim 16, wherein a portion of the bit line is in contact with an upper side surface of the active pattern.

20. The semiconductor memory device of claim 16,
wherein the active pattern comprises an oxide semiconductor, and
wherein an oxygen concentration in a center of the active pattern is higher than an oxygen concentration in a first end portion of the active pattern.
